(19) United States
(12) Patent Application Publication
(10) Pub. No.: US 2025/0391708 A1
(43) Pub. Date: Dec. 25, 2025

(54) SUBSTRATE PROCESSING FOR IMPROVED WAFER THICKNESS UNIFORMITY

(71) Applicant: Applied Materials, Inc., Santa Clara, CA (US)

(72) Inventors: Bocheng Cao, San Jose, CA (US); Palash Gajjar, Santa Clara, CA (US); Xinghua Sun, Fremont, CA (US); Devika Sarkar Grant, Valley Center, CA (US); Benjamin Cherian, San Jose, CA (US); Gene Lee, San Jose, CA (US); Balasubramanian Pranatharthiharan, San Jose, CA (US)

(73) Assignee: Applied Materials, Inc., Santa Clara, CA (US)

(21) Appl. No.: 19/203,330

(22) Filed: May 9, 2025

Related U.S. Application Data
(60) Provisional application No. 63/663,483, filed on Jun. 24, 2024.

(51) Int. Cl. H01L 21/66

(52) U.S. Cl. CPC H01L 22/12

(57) ABSTRACT

Approaches for reducing substrate thickness variation of a substrate are disclosed. One method includes receiving a first etching amount for a plurality of zones of a first substrate when a first thermal application is being provided to the first substrate, determining a mean target thickness of a second substrate, and determining a second etching amount for each of a plurality of zones of the second substrate when a secondary thermal application and the first thermal application are being provided. The method may further include determining an etch correction amount for each zone of the second substrate, and generating a temperature map based on the etch correction amount for each zone of the second substrate, wherein the temperature map indicates a temperature change for each zone of the plurality of zones. The method may further include generating an etching recipe based on the temperature map for etching the second substrate.

### CROSS-REFERENCE TO RELATED APPLICATIONS

The present application claims priority to U.S. Provisional Patent Application No. 63/663,483, filed Jun. 24, 2024, and entitled “Substrate Processing for Improved Wafer Thickness Uniformity,” and incorporates its disclosure herein by reference in its entirety.

### FIELD OF THE DISCLOSURE

The present embodiments relate to substrate processing and, more particularly, to methods for wafer processing to reduce substrate thickness variation.

### BACKGROUND OF THE DISCLOSURE

3D Integration is becoming a reality in semiconductor device manufacturing. One critical process step is the thinning of the wafer, which is often made from silicon. Grinding is used to remove the bulk of the silicon wafer. Currently a multistep sequence of etching processes that may include chemical mechanical planarization (CMP) and/or plasma etching is often used to complete the final thinning of the silicon. However, this conventional process has a number of disadvantages associated therewith including, but not limited to, the complexity of the process, the capability of correction and the associated costs.

Accordingly, improved approaches are needed for processing a substrate to reduce substrate surface thickness asymmetries.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include receiving a first etching amount for each zone of a plurality of zones of a first substrate when a first thermal application is being provided to the first substrate, determining a mean target thickness of a second substrate, and determining a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate. The method may further include determining an etch correction amount for each zone of the plurality of zones of the second substrate, wherein the etch correction amount is the difference between the second etching amount and the first etching amount, and generating a temperature map based on the etch correction amount for each zone of the plurality of zones of the second substrate, wherein the temperature map indicates a temperature change for each zone of the plurality of zones. The method may further include generating an etching recipe based on the temperature map such that the second substrate is etched based on the etching recipe.

In another aspect, a method may include receiving a first etching amount for each zone of a plurality of zones of a first substrate when a first thermal application is being provided to the first substrate, determining a mean target thickness of a second substrate, and determining a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate. The method may further include determining an etch correction amount for each zone of the plurality of zones of the second substrate, wherein the etch correction amount is the difference between the second etching amount and the first etching amount, and generating a temperature map based on the etch correction amount for each zone of the plurality of zones of the second substrate, wherein the temperature map indicates a temperature change for each zone of the plurality of zones. The method may further include generating an etching recipe based on the temperature map, and then etching the second substrate based on the etching recipe.

In yet another aspect, a system may include one or more processors, and memory storing instructions executable by the one or more processors to receive a first etching amount for each zone of a plurality of zones of a first substrate when a first thermal application is being provided to the first substrate, determine a mean target thickness of a second substrate, and determine a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate. The one or more processors may further determine an etch correction amount for each zone of the plurality of zones of the second substrate, wherein the etch correction amount is the difference between the second etching amount and the first etching amount, and generate a temperature map based on the etch correction amount for each zone of the plurality of zones of the second substrate, wherein the temperature map indicates a temperature change for each zone of the plurality of zones. The one or more processors further generate an etching recipe based on the temperature map such that the second substrate is etched based on the etching recipe.

### BRIEF DESCRIPTION OF THE DRAWINGS

The accompanying drawings illustrate exemplary approaches of the disclosure, including the practical application of the principles thereof, as follows:

FIG. 1 is a cross-sectional schematic side view of a processing chamber according to embodiments of the present disclosure;

FIG. 2 is a schematic cross-sectional view of an electrostatic chuck of a substrate support assembly according to embodiments of the present disclosure;

FIG. 3 is a flowchart of a method for improving substrate thickness uniformity according to embodiments of the present disclosure;

FIG. 4A demonstrates a baseline wafer map created for a substrate according to embodiments of the present disclosure;

FIG. 4B demonstrates a thickness map created for the substrate according to embodiments of the present disclosure;

FIG. 4C demonstrates a required MZ OFF etch map created for the substrate according to embodiments of the present disclosure;

FIG. 4D demonstrates an MZ correction map created for the substrate according to embodiments of the present disclosure;

FIG. 4E demonstrates a temperature map created for the substrate according to embodiments of the present disclosure; and

FIG. 4F demonstrates a map of the substrate during an etching process, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments of the present disclosure provide a more efficient and effective approach for reducing substrate total thickness variation (TTV). Some known approaches require at least three etch procedures to achieve a TTV target. Embodiments of the present disclosure include reducing these processing steps into a single cycle. For example, substrate pre-testing, simulation for optimized etch times, and metrology measurements may only need to be performed a single time prior to etching. Advantageously, no hardware changes are needed, as improved results can be achieved via software/algorithm changes only, thus minimizing the cost to implement.

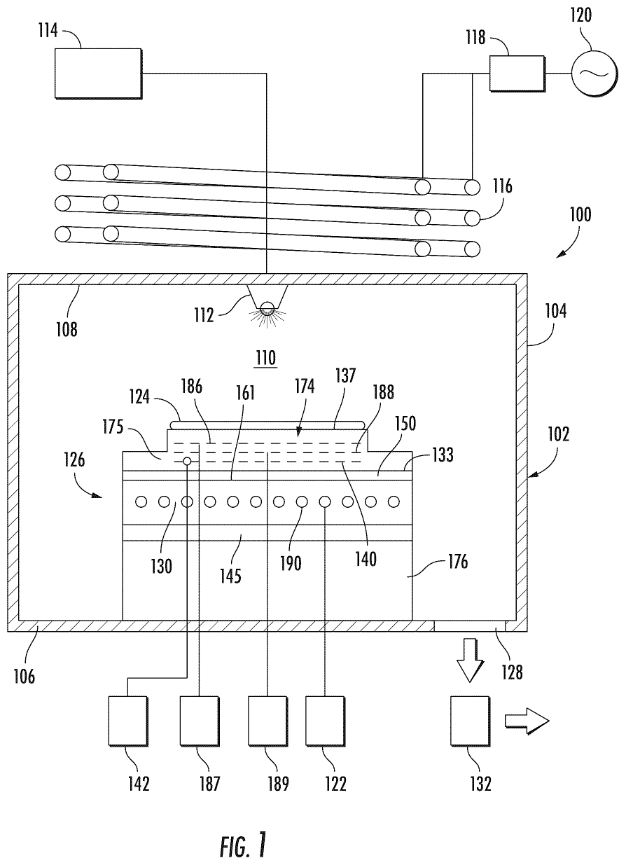

FIG. 1 is a cross-sectional schematic view of an exemplary plasma processing chamber 100, shown configured as an etch chamber, having a substrate support assembly 126 therein. The plasma processing chamber 100 may be one example of a chamber suitable for processing (e.g., etching) a wafer or substrate 124 to reduce TTV and asymmetry of a surface of the substrate 124. The substrate support assembly 126 may be utilized in other types of processing plasma chambers, e.g., plasma treatment chambers, annealing chambers, physical vapor deposition chambers, chemical vapor deposition chambers, and ion implantation chambers, among others, as well as other systems where the ability to control processing uniformity for a surface or workpiece, such as a substrate, is desirable.

The plasma processing chamber 100 may include a chamber body 102 having sidewalls 104, a bottom and a lid 108 that enclose an interior processing region 110. An injection apparatus 112 may be coupled to the sidewalls 104 and/or lid 108 of the chamber body 102. A gas panel 114 may be coupled to the injection apparatus 112 to allow process gases to be provided into the processing region 110. The injection apparatus 112 may include one or more nozzle or inlet ports, or alternatively, a showerhead. Processing gas, along with any processing by-products, are removed from the processing region 110 through an exhaust port 128 formed in the sidewalls 104 or bottom 106 of the chamber body 102. The exhaust port 128 may be coupled to a pumping system 132, which includes throttle valves and pumps utilized to control the vacuum levels within the processing region 110.

The processing gas may be energized to form a plasma within the processing region 110, wherein the processing gas may be energized by capacitively or inductively coupling RF power to the processing gases. In the embodiment depicted in FIG. 1, a plurality of coils 116 are disposed above the lid 108 of the plasma processing chamber 100 and are coupled through a matching circuit 118 to an RF power source 120. Power applied to the plurality of coils 116 generates plasma within the processing region 110.

The substrate support assembly 126 is disposed in the processing region 110 below the injection apparatus 112. The substrate support assembly 126 may include a platen or substrate support, such as an electrostatic chuck (ESC) 174 and a cooling base 130. The cooling base 130 may optionally be supported by a base plate 176. The base plate 176 is supported by one of the sidewalls 104 or bottom 106 of the plasma processing chamber 100. Additionally, the substrate support assembly 126 may include a facility plate 145 and/or an insulator plate (not shown) disposed between the cooling base 130 and the base plate 176 to facilitate electrical, cooling, and gas connections with the substrate support assembly 126. It will be appreciated that the substrate support assembly 126 is non-limiting, and may vary in alternative embodiments.

The cooling base 130 is formed from a metal material or other suitable material. For example, the cooling base 130 may be formed from aluminum (Al). The cooling base 130 includes cooling channels 190 formed therein. The cooling channels 190 are connected to a heat transfer fluid source 122 by a transfer fluid conduit 192. The heat transfer fluid source 122 provides a heat transfer fluid, such as a liquid, gas or combination thereof, which is circulated through the cooling channels 190 in the cooling base 130. In one embodiment, the heat transfer fluid circulating through the cooling channels 190 of the cooling base 130 maintains the cooling base 130 at a temperature between about 30 degrees Celsius and about 120 degrees Celsius or at a temperature lower than 90 degrees Celsius.

The ESC 174 includes one or more chucking electrodes 186 disposed in a dielectric body 175. The dielectric body 175 has a workpiece support surface 137 and a bottom surface 133 opposite the workpiece support surface 137. Although non-limiting, the dielectric body 175 of the ESC 174 may be fabricated from a ceramic material, such as alumina (Al₂O₃), aluminum nitride (AlN), or other suitable material. Alternately, the dielectric body 175 may be fabricated from a polymer, such as polyimide, polyetheretherketone, polyaryletherketone, and the like.

The dielectric body 175 includes one or more primary resistive heaters 188 embedded therein. The primary resistive heaters 188 may alternatively be located in another portion of the substrate support assembly 126. The primary resistive heaters 188 are utilized to provide a first/primary thermal application to elevate the temperature of the substrate support assembly 126 to a temperature suitable for processing the substrate 124 disposed on the workpiece support surface 137 of the substrate support assembly 126. The primary resistive heaters 188 are coupled through the facility plate 145 to a heater power source 189. The heater power source 189 provides power to the primary resistive heaters 188. A controller 142 is utilized to control the operation of the heater power source 189, which is generally set to heat the substrate 124 to a desired temperature.

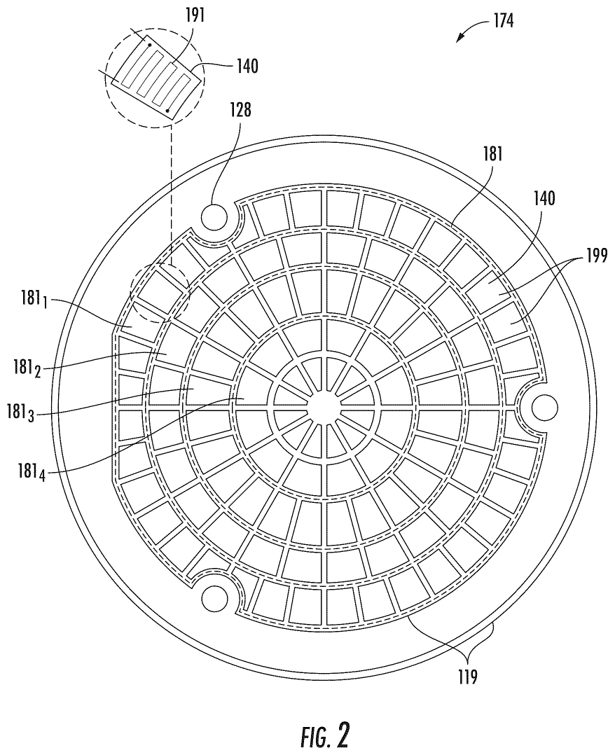

In one embodiment, the primary resistive heaters 188 are arranged in a plurality of laterally separated heating zones, wherein the controller 142 enables at least one zone of the primary resistive heaters 188 to be individually heated relative to the primary resistive heaters 188 located in one or more of the other zones. For example, the primary resistive heaters 188 may be arranged concentrically in a plurality of radially separated primary heater zones (shown in FIG. 2 as item 181). In one example, the primary resistive heaters 188 are arranged in four concentric primary heater zones 181, a first primary heater zone 181₁, a second primary heater zone 181₂, a third primary heater zone 181₃, and a fourth primary heater zone 181₄. Embodiments herein are not limited in this context, however. The primary resistive heaters 188 may maintain the substrate 124 at a temperature suitable for processing, such as between about 180 degrees Celsius to about 500 degrees Celsius. When the primary resistive heaters 188 are turned off, the substrate 124 may be at room temperature or ambient temperature, i.e., the temperature within interior processing region 110.

The ESC 174 may optionally include a plurality of secondary heaters 140. The number of secondary heaters 140 may be an order of magnitude greater than the number of primary resistive heaters 188. The secondary heaters 140 may provide a secondary thermal application to control the temperature of the ESC 174 at a micro level, such as plus or minus 5 degrees Celsius, while the primary resistive heaters 188 control the temperature of the ESC 174 at a macro level. The ESC 174 may also have a plurality of micro zones, such as 50 to 150 micro zones or more, that are temperature controlled by the secondary heaters 140. The secondary heaters 140 form temperature control in small discrete locations, i.e., micro-zones on the ESC 174, which is transferred to the substrate 124. During the secondary thermal application, both the primary resistive heaters 188 and the secondary heaters 140 are operational (‘multizone (MZ) ON’). During the primary thermal application, only the primary resistive heaters 188 are operational (‘MZ OFF’), while the secondary heaters 140 are off.

FIG. 2 is a schematic cross-sectional view of the ESC 174 of the substrate support assembly 126 illustrating the plurality of secondary heaters 140. The ESC 174 illustrates one embodiment for the plurality of secondary heaters 140. The secondary heaters 140 may be configured in a pattern to efficiently generate a heat profile along the surface of the substrate support assembly 126. The pattern may be symmetric about a midpoint while providing clearance in and around holes for lift pins or other mechanical, fluid or electrical connections. Other patterns or arrangements may be possible in alternative embodiments. The secondary heaters 140 are arranged in a plurality of cells, i.e., micro zones 199. It is contemplated that each secondary heater 140 occupies a respective single micro-zone 199. A thermal choke 119 may be disposed between each neighboring micro-zone 199. Additionally, the thermal choke 119 may be disposed along an outer perimeter of the ESC 174. The thermal choke 119 limits heat transfer from adjacent micro zones to prevent heat smearing and true thermal control of each micro-zone 199 by its respective secondary heater 140.

The number of micro zones 199 shown is for illustrative purposes only, and it is contemplated that the number and arrangement of micro zones 199 could exceed 50 or more, such as 150 or more zones. Thus, the number of secondary heaters 140 located across the substrate support assembly 126 may easily be in excess of several hundred. Each micro-zone 199 of the secondary heaters 140 occupies a single one of the primary heater zones 181. A boundary or thermal choke 119 of the micro-zone 199 is coincident with a boundary 182 of a respective primary heater zone 181, for example, the first primary heater zone 1811, such that the micro-zone 199 is fully contained in only the first primary heater zone 1811 and does not extend into the second primary heater zone 1812.

In some embodiments, each secondary heater 140 has a resistor 191 ending in terminals. As current enters one terminal and exists the other terminal the current travels across the wire of the resistor and generates heat. The amount of heat released by the resistor 191 is proportional to the square of the current passing therethrough. The power design density may be between about 1 watt/cell to about 100 watt/cell, such as 10 watt/cell. Embodiments herein are not limited in this context, however.

Returning to FIG. 1, each secondary heater 140 may be controlled by the controller 142 or by an additional controller (not shown). The controller 142 may turn on a single secondary heater 140, or may turn on a plurality of secondary heaters 140, either grouped together or spaced apart. In this manner, temperatures can be precisely controlled at independent locations along the micro zones 199 formed in the ESC 174. Although the pattern shown is comprised of smaller units, the pattern may alternatively have larger and/or smaller units, extend to the edge, or have other forms to form 150 or more discrete micro zones 199.

The ESC 174 generally includes a chucking electrode 186 embedded in the dielectric body 175. The chucking electrode 186 may be configured as a mono polar or bipolar electrode, or other suitable arrangement. The chucking electrode 186 is coupled through an RF filter to a chucking power source 187, which provides a DC power to electrostatically secure the substrate 124 to the workpiece support surface 137 of the ESC 174. The RF filter prevents RF power utilized to form a plasma (not shown) within the plasma processing chamber 100 from damaging electrical equipment or presenting an electrical hazard outside the chamber.

The workpiece support surface 137 of the ESC 174 includes gas passages (not shown) for providing backside heat transfer gas to the interstitial space defined between the substrate 124 and the workpiece support surface 137 of the ESC 174. The ESC 174 may also include lift pin holes for accommodating lift pins (not shown) for elevating the substrate 124 above the workpiece support surface 137 of the ESC 174 to facilitate robotic transfer into and out of the plasma processing chamber 100.

A bonding layer 150 is disposed below the ESC 174 and secures the ESC 174 to the cooling base 130. In other embodiments, the bonding layer 150 is disposed between the ESC 174 and a lower plate that is disposed between the ESC 174 and cooling base 130.

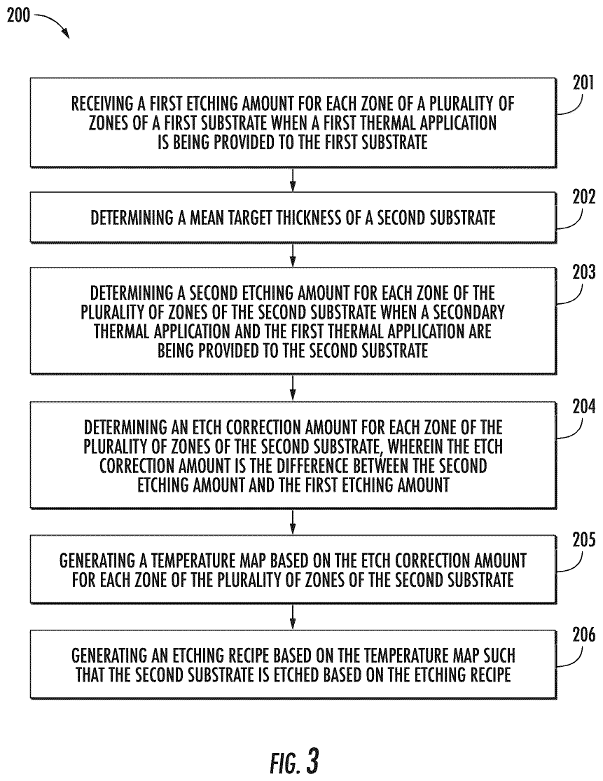

FIG. 3 is a flowchart of a method 200 for etching a substrate to reduce substrate thickness variation according to embodiments of the present disclosure. Portions of the method 200 will be described with reference to the plasma processing chamber 100 described above and shown in FIGS. 1-2.

At block 201, the method 200 may include receiving a first etching amount for each zone of a plurality of zones of a first substrate when a first thermal application is being provided to the first substrate. In some embodiments, a processor may receive a first etching amount for each of the plurality of zones of a first/test substrate, the first etching amount being previously determined from the test substrate, or from multiple test substrates. The first etching amount may be determined based on an etch rate for each of the plurality of zones of the test wafer while the primary resistive heaters 188 are active and the secondary heaters 140 are inactive. Although non-limiting, the plurality of zones of the first substrate may generally correspond to the plurality of primary heater zones 181. The etch rates determined for each of the plurality of zones of the first substrate may be used to establish an intrinsic etch variation baseline for the plasma processing chamber 100.

At block 202, the method 200 may include determining a mean target thickness of a second substrate. In some embodiments, the mean target thickness is predetermined and/or user selected for the second substrate 124. In other embodiments, the mean target thickness may be determined based on observed thickness variations of the second substrate 124. For example, a metrology scan may be performed on the second substrate 124 to establish thickness values for each of the plurality of zones. To reduce TTV between zones of the second substrate 124, the target thickness may correspond to a thinnest zone, or to a grouping of relatively thinner zones, of the plurality of zones.

At block 203, the method 200 may include determining a second etching amount for each zone of the plurality of zones of the second substrate when a secondary thermal application and the first thermal application are being provided to the second substrate, wherein the second etching amount is the difference between a thickness of the second substrate at each zone of the plurality of zones and the mean target thickness of the second substrate. In some embodiments, the results of the previously performed metrology scan may be provided to the processor to determine the difference between the thickness of the second substrate 124 at each zone of the plurality of zones and the mean target thickness of the second substrate 124 while the primary resistive heaters 188 and the secondary heaters 140 are both active.

At block 204, the method 200 may include determining an etch correction amount for each zone of the plurality of zones of the second substrate, wherein the etch correction amount is the difference between the second etching amount and the first etching amount.

At block 205, the method 200 may include generating a temperature map based on the etch correction amount for each zone of the plurality of zones of the second substrate, wherein the temperature map indicates a temperature change for each zone of the plurality of zones. For example, those zones of the plurality of zones with higher correction amounts may be assigned a higher temperature value than those zones of the plurality of zones with a lower (or no) correction amount, as higher temperatures are generally associated with higher etch rates.

At block 206, the method 200 may include generating an etching recipe based on the temperature map such that the second substrate is etched based on the etching recipe. Although non-limiting, the etching recipe may include an ion etch chemistry, selected based on the material(s) of the second substrate 124, ion implant energy, etching duration, temperature, and more.

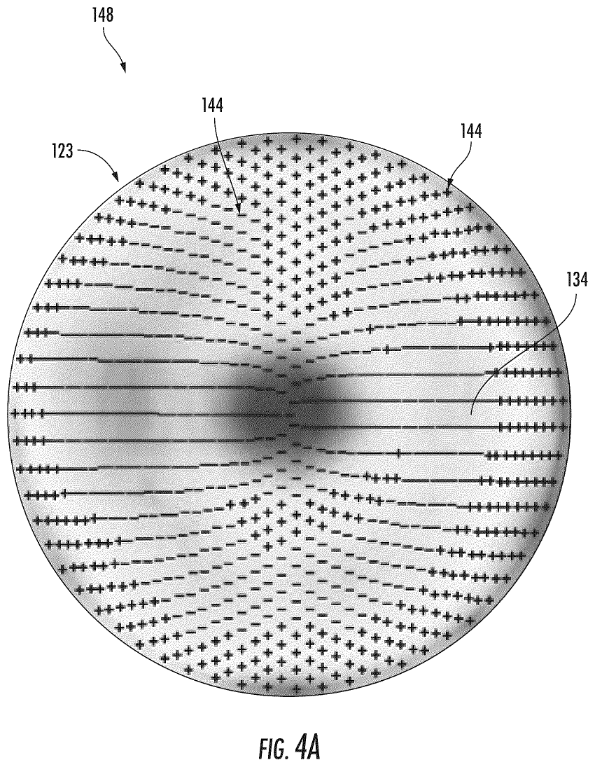

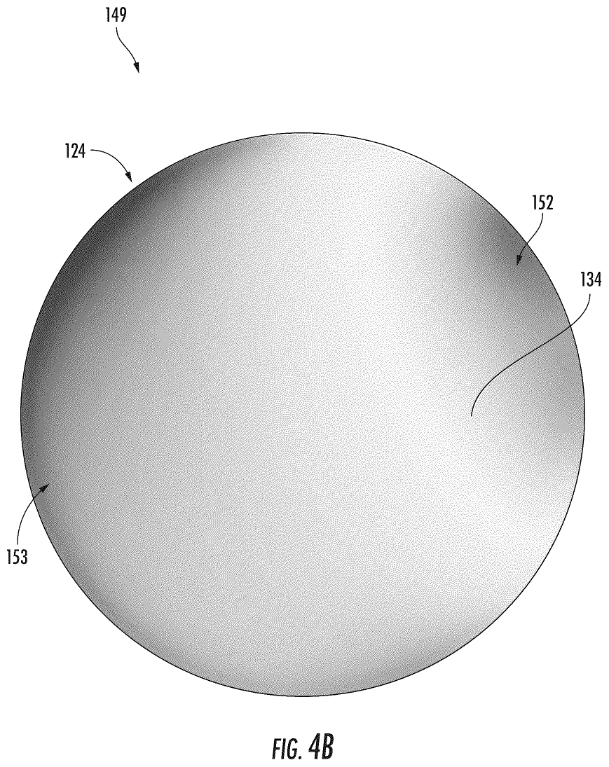

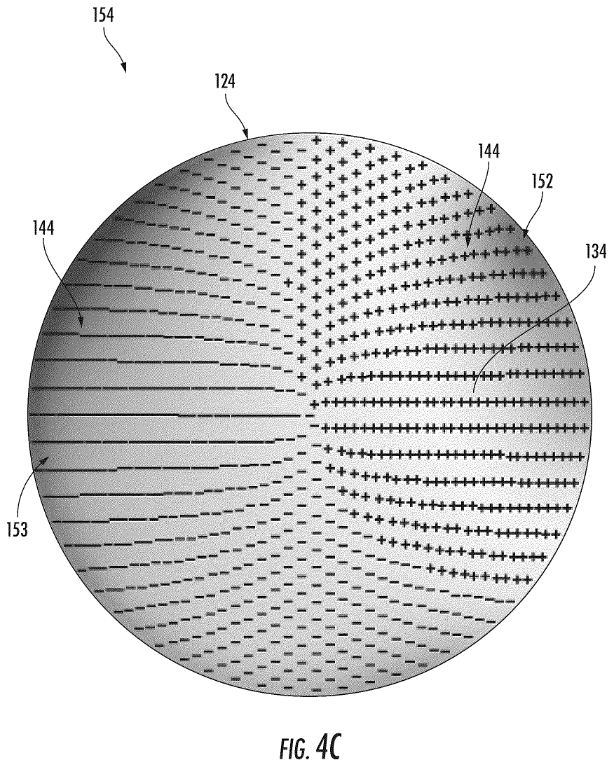

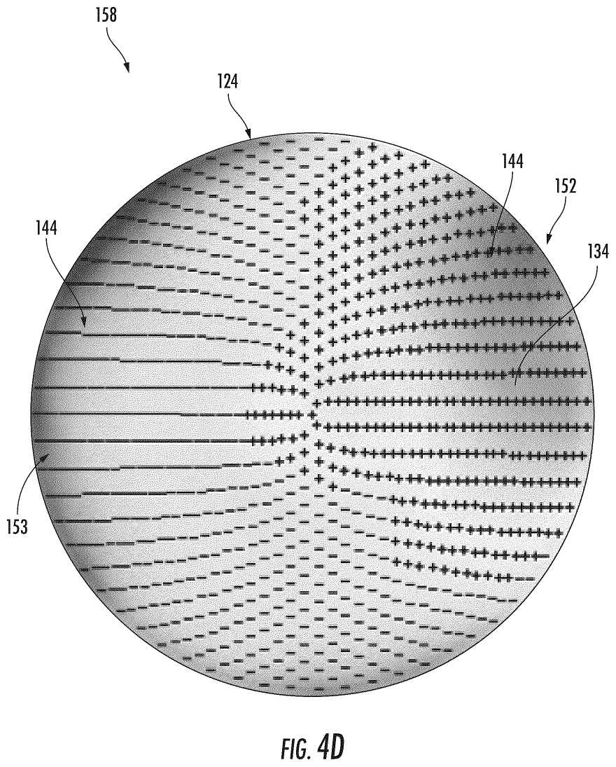

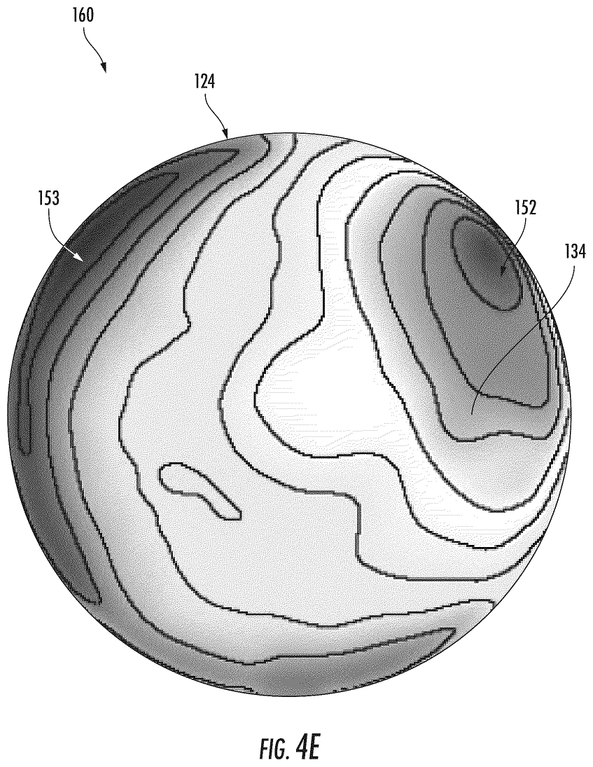

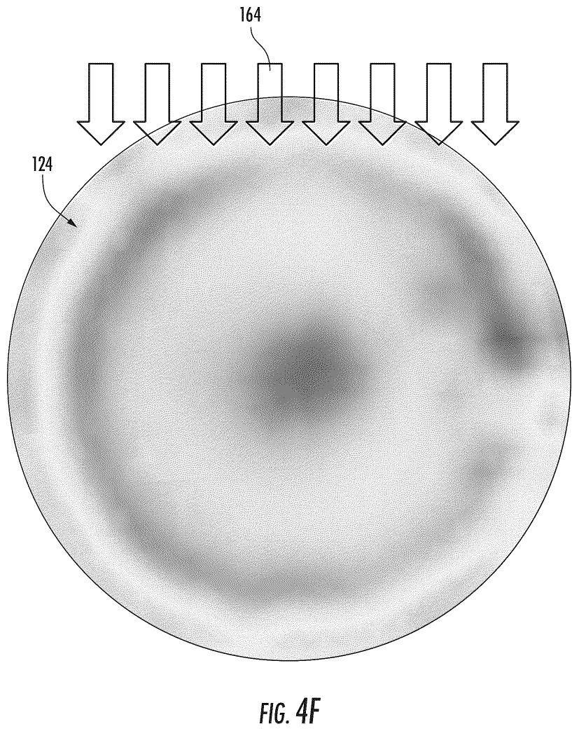

Turning now to FIGS. 4A-4F, the method 200 will be described in greater detail with reference to one or more substrates. As shown in FIG. 4A, a baseline wafer map 148 may be created for a first substrate 123. In this embodiment, a first main side 134 of the first substrate 123 may be divided into a plurality of zones 144, as indicated by (+) and (−) symbols. In some embodiments, each of the plurality of zones 144 may map to a corresponding zone of the plurality of primary heater zones 181. It will be appreciated that the size, shape, and number of zones 144 may vary in other embodiments from what's depicted. Baseline wafer map 148 may be used to determine a first etching amount for each of the plurality of zones 144 of the first substrate 123 when a first thermal application is being provided to the first substrate 123. More specifically, the first etching amount may be determined based on an etch rate for each of the plurality of zones 144 of the first substrate 123 while the primary resistive heaters 188 are active but the secondary heaters 140 are inactive.

As shown in FIG. 4B, a thickness map 149 may be generated for a second substrate 124 based on the baseline wafer map 148. In some embodiments, the thickness map 149 may be generated based on feedback from a metrology scan. In this non-limiting example, the thickness map 149 demonstrates that the second substrate 124 has a relatively thicker section 152 and a relatively thinner section 153. Based on the thickness map 149, a mean target thickness for the second substrate 124 and an etch time to meet the mean thickness target for the second substrate 124, may be determined. In some embodiments, the mean target thickness is predetermined and/or user selected for the second substrate 124. In other embodiments, the mean target thickness may be determined based on the feedback from the metrology scan. Either way, the mean target thickness for the second substrate 124 may be determined while the secondary 140 heaters are off and the primary resistive heaters 188 are on. In some embodiments, the etch time can be determined by dividing the mean required etch amount by the etch rate.

As shown in FIG. 4C, a required MZ ON etch map 154 may be created for the second substrate 124 while both the primary resistive heaters 188 and the secondary heaters 140 are active. The required MZ ON etch map 154 may be generated based on a difference between the mean target thickness for each zone 144 and the calculated thickness for each zone 144, and is used to determine a second etching amount for each of the plurality of zones 144 of the second substrate 124. It can be seen by the number of zones 144 designated with the (+) symbol verses the number of zones 144 designated with the (−) symbol, that the relatively thicker section 152 requires greater etching than the relatively thinner section 153.

As shown in FIG. 4D, an MZ correction map 158 for the second substrate 124 may be generated based on a difference between the first etching amount of the baseline wafer map 148 of the first substrate 123 and the second etching amount of the required MZ ON etch map 154. The MZ correction map 158 demonstrates the actual thickness amount needed to be corrected/tuned for each of the zones 144 of the second substrate 124.

As shown in FIG. 4E, a temperature map 160 for the second substrate 124 may then be generated based on the MZ correction map 158. For example, the temperature map 160 may associate a higher temperature with the relatively thicker section 152 of the second substrate 124, and associate a lower temperature with the relatively thinner section 153 of the second substrate 124. In some embodiments, the temperature map 160 may include temperature values for each of the zones 144.

As shown in FIG. 4F, based on the temperature map 160, an etching recipe may be generated and then used by a processing tool (e.g., processing chamber 100) to etch 164 the second substrate 124. As a result of the etch 164, the relatively thicker section 152 of the second substrate 124 has been eliminated or reduced to improve thickness uniformity of the second substrate 124.

Although not shown, the processing steps demonstrated in FIGS. 4B-4F may be repeated for one or more additional target wafers. Advantageously, data from the first substrate 123 (i.e., test wafer) can be applied to the additional target wafers without the need to perform the processing step shown in FIG. 4A. For example, the first etching amount for each zone 144 of the first substrate 123 can be stored and subsequently received/applied to generate the etching recipe for the one or more additional target wafers.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
receiving a first etching amount for each zone of a plurality of zones of a first substrate when a first thermal application is being provided to the first substrate;
determining a mean target thickness of a second substrate;
determining a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate;
determining an etch correction amount for each zone of the plurality of zones of the second substrate, wherein the etch correction amount is the difference between the second etching amount and the first etching amount;
generating a temperature map based on the etch correction amount for each zone of the plurality of zones of the second substrate, wherein the temperature map indicates a temperature change for each zone of the plurality of zones; and
generating an etching recipe based on the temperature map such that the second substrate is etched based on the etching recipe.

2. The method of claim 1, further comprising etching the second substrate, using an etching tool, based on the etching recipe.

3. The method of claim 1, wherein the secondary thermal application comprises heating the second substrate according to the temperature change for each zone of the plurality of zones.

4. The method of claim 1, wherein determining the second etching amount for each zone of the plurality of zones comprises:
determining a target etch time to achieve the mean target thickness; and
multiplying a baseline etch rate for each of the plurality of zones by the target etch time.

5. The method of claim 4, wherein determining the target etch time comprises dividing a mean required etch amount by the baseline etch rate.

6. The method of claim 1, wherein determining the thickness of the second substrate at each zone of the plurality of zones comprises performing a metrology scan of a first main side of the second substrate.

7. The method of claim 1, further comprising providing the second substrate atop a substrate support, wherein the substrate support is operable to provide the first thermal application and the secondary thermal application to the substrate.

8. The method of claim 1, further comprising determining the first etching amount for each zone of the plurality of zones of the first substrate when the first thermal application is being provided to the first substrate.

9. A method comprising:
determining a first etching amount for each zone of a plurality of zones of a first substrate when a first thermal application is being provided to the first substrate;
determining a mean target thickness of a second substrate;
determining a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate;
determining an etch correction amount for each zone of the plurality of zones of the second substrate, wherein the etch correction amount is the difference between the second etching amount and the first etching amount;
generating a temperature map based on the etch correction amount for each zone of the plurality of zones of the second substrate, wherein the temperature map indicates a temperature change for each zone of the plurality of zones;
generating an etching recipe based on the temperature map; and
etching the second substrate according to the etching recipe using an etching tool.

10. The method of claim 9, wherein the secondary thermal application comprises heating the second substrate according to the temperature change for each zone of the plurality of zones.

11. The method of claim 9, wherein the secondary thermal application further comprises independently controlling an amount of heat provided to each zone of the plurality of zones.

12. The method of claim 9, further comprising performing a metrology scan of a first main side of the second substrate to determining the thickness of the second substrate at each zone of the plurality of zones.

13. The method of claim 9, further comprising supplying the first thermal application and the secondary thermal application to the second substrate via a substrate support.

14. A system, comprising:
one or more processors;
memory storing instructions executable by the one or more processors to:
receive a first etching amount for each zone of a plurality of zones of a first substrate when a first thermal application is being provided to the first substrate;
determining a mean target thickness of a second substrate;
determine a second etching amount for each zone of a plurality of zones of the second substrate when a secondary thermal application and the first thermal application are being provided to the second substrate, wherein the second etching amount is the difference between a thickness of the second substrate at each zone of the plurality of zones and the mean target thickness of the second substrate;
determine an etch correction amount for each zone of the plurality of zones of the second substrate, wherein the etch correction amount is the difference between the second etching amount and the first etching amount;
generate a temperature map based on the etch correction amount for each zone of the plurality of zones of the second substrate, wherein the temperature map indicates a temperature change for each zone of the plurality of zones; and
generate an etching recipe based on the temperature map such that the second substrate is etched based on the etching recipe.

15. The system of claim 14, further comprising instructions executable by the one or more processors to etch the second substrate, using an etching tool, based on the etching recipe.

16. The system of claim 14, wherein the secondary thermal application comprises heating the second substrate according to the temperature change for each zone of the plurality of zones, and wherein the second substrate is heated prior to etching the second substrate.

17. The system of claim 14, wherein the secondary thermal application comprises independently controlling an amount of heat provided to each zone of the plurality of zones.

18. The system of claim 14, further comprising instructions executable by the one or more processors to perform a metrology scan of a first main side of the second substrate to determine the thickness of the second substrate at each zone of the plurality of zones.

19. The system of claim 14, further comprising instructions executable by the one or more processors to supply the first thermal application and the secondary thermal application to the second substrate via a substrate support.

20. The system of claim 14, further comprising instructions executable by the one or more processors to determine the first etching amount for each zone of the plurality of zones of the first substrate when the first thermal application is being provided to the first substrate.
